(19) United States
(12) Patent Application Publication
(10) Pub. No.: US 2024/0383928 A1
(43) Pub. Date: Nov. 21, 2024

(54) PRODUCTION OF DIORGANOTIN DIHALIDES

(71) Applicant: Merck Patent GmbH, Darmstadt (DE)

(72) Inventors: Robert VINCENT, Sheboygan, WI (US); Jarrod C. ZIMMERMANN, Manitowoc, WI (US)

(21) Appl. No.: 18/576,805

(22) PCT Filed: Jul. 28, 2022
(86) PCT No.: PCT/EP22/71186

§ 371 Date: Jan. 5, 2024

Related U.S. Application Data
(60) Provisional application No. 63/227,523, filed on Jul. 30, 2021.

(51) Int. Cl. C07F 7/22

(52) U.S. Cl. CPC C07F 7/2208

(57) ABSTRACT

The disclosed and claimed subject matter relates to the safe and efficient synthesis of diorganotin dihalide compounds of the formula R2SnX2 that as-synthesized are free of tetraalkyltin (R₄Sn), trialkyltin halide (R₃SnX) and monoalkyltin trihalide (RSnX3) species and of methods for their synthesis and use.

### BACKGROUND

### Field

The disclosed and claimed subject matter relates to the safe and efficient synthesis of diorganotin dihalide compounds of the formula R₂SnX₂ that as-synthesized are free of the corresponding tetraalkyltin (R₄Sn), trialkyltin halide (R₃SnX) and monoalkyltin trihalide (RSnX₃) species and of methods for their synthesis and use.

### Related Art

The semiconductor industry is currently considering the use of metal-containing materials as EUV (extreme ultraviolet) photoresist material for patterning. Many organometallic complexes especially tin-containing compounds have been evaluated as potential precursors for the formation of photoresist material via either spin coating or chemical vapor deposition. Production of organotin precursors for EUV patterning applications involve a series of steps using ubiquitous halo and organotin starting materials and transforming them to final products. One of the primary starter materials is tetramethyl tin (Me₄Sn). Tetramethyl tin, however, is extremely toxic and there is a strong desire to replace this compound as a starting material for other materials for use in EUV processes.

For example, U.S. Pat. No. 10,787,466 discloses compositions of monoalkyltin trialkoxide compounds of formula RSn(OR′)₃ or monoalkyltin triamide compounds of formula RSn(NR′₂)₃ where (i) R is a hydrocarbyl group with 1-31 carbon atoms, and where R′ is a hydrocarbyl group with 1-10 carbon atoms and (ii) the compositions contain no more than 4 mol % of dialkyltin compounds relative to the total amount of tin. Also disclosed is a composition including a monoalkyl triamidotin compound of formula RSn—(NR′COR″)₃ where R is a hydrocarbyl group with 1-31 carbon atoms, and where R′ and R″ are independently a hydrocarbyl group with 1-10 carbon atoms. It is believed that having the dialkyltin compounds (as impurities) in the formulation affects performance.

WO2019246254 discloses precursor solutions for radiation patternable coatings that are formed with an organic solvent and monoalkyltin trialkoxides in which the water content of the solvent is adjusted to be within 10% of a selected value. Generally, the water content of the solvent is adjusted through the addition of water, although water removal can also be used. For example, in some embodiments, the adjusted water content of the solvent can be from about 250 ppm by wt. to about 10,000 ppm by wt. With the appropriate selection of ligands, the adjusted precursor solutions are asserted to be stable for at least about 42 days, and in some cases at least 8 months.

U.S. Pat. No. 10,732,505 discloses organometallic precursors for the formation of high-resolution lithography patterning coatings based on metal oxide hydroxide chemistry. The precursor compositions generally include ligands that are readily hydrolysable by water vapor or other —OH source under modest conditions. In particular, the organometallic precursors include a radiation sensitive organo ligand to tin that can result in a coating that can be effective for high-resolution patterning at relatively low radiation doses and is particularly useful for EUV patterning.

WO2018179704 describes a method for pattern formation that includes: (1) applying a compound for forming an underlayer film to a substrate; (2) applying a radiation sensitive compound for forming a resist film directly or indirectly to the underlayer film; (3) exposing the resist film to light; and (4) developing the resist film which has been exposed to light. The compound contains (i) a first component which produces a component having an acid group selected from a sulfo group, a carboxy group, a phosphono group, a phosphoric acid group, a sulfuric acid group, a sulfone amide group, a sulfonyl imide group, a —CR F¹R F²—OH group or a combination of these groups by the action of heat and (ii) a second component which is differs than the first component but is one of acid groups described above. The radiation sensitive compound contains 50% by mass or more of a metal-containing compound in terms of solid content.

Typically, organotin chlorides have been employed as starting materials to prepare tin-containing compounds described in the above patents and publications. There is a very limited number of synthetic routes for preparing alkyltin chlorides, none of which are suitable for the safe and large-scale production of these materials without producing highly toxic by-products.

For example, the reaction of polymeric diorganotin oxides, (R₂SnO)ₙ (R=Me, Et, Bu, C₈H₁₇, Cy, iPr, Ph), with saturated aqueous NH₄X (X═F, Cl, Br, I, OAc) in refluxing 1,4-dioxane afforded in high yields dimeric tetraorganodistannoxanes, [R₂(X)SnOSn(X)R₂]₂, and in some cases diorganotin dihalides or diacetates, R₂SnX₂ has been described. See J. Beckmann et al., “A novel route for the preparation of dimeric tetraorganodistannoxanes.” J. Organomet. Chem., 659 (1-2): 73-83 (2002). The reported method appears suitable for the synthesis of fluorinated tetraorganodistannoxanes. The co-existence of [Bu₂(OH)SnOSn(X)Bu₂]₂ (X═Cl, Br) and [Bu₂(OH)SnOSn(X)Bu₂][Bu₂(X)SnOSn(X)Bu₂] in the reaction mixture (established on the basis of tin-119 NMR spectra) suggests a serial substitution mechanism starting from [R₂(OH)SnOSn(OH)R₂]₂. Redistribution of halogens between [Cy₂(F)SnOSn(F)Cy₂]₂ and [Cy₂(Cl)SnOSn(Cl)Cy₂]₂ gave mixed halide [Cy₂(F)SnOSn(Cl)Cy₂]₂ in quantitative yield. X-ray crystal structure data is reported for [Me₂(AcO)SnOSn(OAc)Me₂]₂, [iPr₂(Br)SnOSn(Br)iPr₂]₂, [Cy₂(F)SnOSn(F)Cy₂]₂. These show the presence of a central (R₂Sn)₂O₂ core that is connected, via the oxygen atoms, to R₂Sn entities. Acetate or halides complete the coordination about the tin centers.

U.S. Pat. No. 2,675,399 discloses organotin halides are prepared from Sn halides with Mg and organic halides in a single step. Hydrocarbons are used as solvents and the reaction is run at 65° C.-185° C. In a typical example, 1.5 mL of EtBr, 12 mL of Et₂O, 4.5 g. of BuCl, and 30 mL of MePh treated with 24.5 g. of Mg, stirred until a reaction commenced, and treated with a mixture of 88 g. of BuCl, 250 mL of MePh, and 98.5 g. of BuSnCl₃ to yield, after treatment with H₂O, 8.8 g. of Bu₂SnCl₂, 91.7 g. of Bu₃SnCl, and 7.2 g. of Bu₄Sn, respectively. Similarly, a little iodine was added to 5 mL of BuCl, 5 mL of Et₂O, and 24.4 g. of Mg, and when the reaction started, 50 mL of MePh was added followed by 151.9 g. of Bu₂SnCl₂ in 160 mL of MePh. The mixture was then slowly heated to 95° C., treated gradually with BuCl (total 92.5 g.) along with 1 mL of EtBr, and refluxed several hours to yield 0.3 g. of Bu₂SnCl₂, 77.2 g., of Bu₃ SnCl, and 72 g. of Bu₄Sn.

Notwithstanding the above syntheses, many of the produced organotin compounds are highly toxic or require the use of toxic starting materials to produce (which in turn results in materials having toxic impurities). This is of particular concern considering the extensive use of tin compounds. In fact, tin has been reported to have a larger number of its organometallic derivatives in commercial use than any other element. See M. Hoch, “Organotin compounds in the environment—an overview,” Appl. Geochem., 16(7-8): 719-743 (2001). The increased worldwide production of organotin compounds during the last 50 years has resulted in considerable amounts of organotins having entered various ecosystems. While Sn in its inorganic form is considered to be nontoxic, the toxicological pattern of the organotin compounds is complex. Depending on the nature and number of organic groups bound to the Sn cation, some organotins show specific toxic effects to different organisms even at very low concentrations. Therefore, the specific determination of the individual organotin compounds is required. In recent years new sensitive analytical techniques have been developed for the detection of organotin compounds in various environmental samples. High amounts of toxic tributyltin and some other organotin derivatives can be found not only in water and sediments, but also in various aquatic organisms as well as tissues of mammals and birds are contaminated by these compounds. Indeed, other studies of human blood and livers show enhanced concentrations for some organotin derivatives.

For example, it has been shown through clinical observations that poisoning by Sn alkyls exhibit symptoms similar to those from Pb(C₂H₅)₄. See W. Zeman et al., “The genesis of disturbances of circulatory regulation. Toxic effect of tin peralkyls,” Dtsch. Arch. Klin. Med., 198: 713-721 (1951). Other studies have shown that Sn alkyls are readily absorbed through skin or lungs. Toxicologic tests by intraperitoneal injection on mice show that the 2-hr. LD50 for Sn(CH₃)₄ is 140 mg./kg.; for Sn(C₂H₅)4, 660 mg./kg. The 24-hr. figures are, respectively, 18 mg./kg and 130 mg./kg. These results suggest a chronic toxic effect of the metal alkyl. With N(C₂H₅)₄Cl the LD50 is “only” 60 mg./kg., but all animals that survived for 25 minutes recovered.

It has also been shown that mono-, di-, and trimethyltins are toxic to microorganisms from water sediments, and the di-and tri-methyl compounds were more toxic than the monomethyl compound as measured by either viable counts or by [3H] thymidine uptake. See G. W. Pettibone, and J. J. Cooney, “Toxicity of methyltins to microbial populations in estuarine sediments.” J. Ind. Microbiol., 2(6): 373-378 (1988) (examining and disclosing the toxicities of 3 organotin compounds on natural populations of microorganisms in sediments from Boston Harbor).

Thus, although there are many routes in the literature to produce diorganotin dihalide materials (e.g., dimethyltin dichloride) they are both complicated/expensive (e.g., the redistribution method employed using tetramethyl tin and tin tetrachloride, many are direct methods, employing catalyst and higher temperature, others use molten tin and methylchloride, whilst others are traditional adding Grignard to tin tetrachloride) and/or rely on toxic materials. As such, there is a need to develop diorganotin dihalide that as-synthesized have little or no toxic impurities and that are produced by economically viable and environmentally safe procedures. In addition, there is a need to develop new synthetic routes which do not utilize toxic starting materials (e.g., tetrametyltin) as in the case of the conventional synthetic method via reacting tetraorganotin with tin tetrahalides to prepare diorganotin dihalides. There is also a need to provide an environmentally friendly process for synthesizing diorganotin dihalides that are free of toxic materials as-synthesized whereby the waste streams from production and/or purification are free of hazardous and/or toxic unreacted starting materials (e.g., tetramethyl tin and partially reacted trimethylchlorotin) and which thereby also results in less downstream points of contact with these hazardous substances (e.g., in filtrates).

### SUMMARY

In one embodiment the disclosed and claimed subject matter relates to diorganotin dihalide compounds of the formula R₂SnX₂ (where (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group and (ii) X is Cl, Br, F or I) that as-synthesized (i.e., without further purification) are free of the corresponding tetraalkyltin (R₄Sn), trialkyltin halide (R₃SnX) and monoalkyltin trihalide (RSnX₃) species. In one aspect of this embodiment, R is a methyl group. In another aspect of this embodiment, R is an ethyl group. In one aspect of this embodiment, X is Cl. In another aspect of this embodiment, R is a methyl group and X is Cl. In another aspect of this embodiment, R is an ethyl group and X is Cl.

In another embodiment, the disclosed and claimed subject matter relates to the synthesis of diorganotin dihalide compounds of the formula R₂SnX₂ from a diorganotin oxide (R₂SnO) according to synthesis (I):

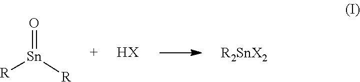

where (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group and (ii) X is Cl, Br, F or I that as-synthesized (i.e., without further purification) are inherently free of the corresponding tetraalkyltin (R₄Sn), trialkyltin halide (R₃SnX) and monoalkyltin trihalide (RSnX₃) species. In one aspect of this embodiment, R is a methyl group. In another aspect of this embodiment, R is an ethyl group. In one aspect of this embodiment, X is Cl. In another aspect of this embodiment, R is a methyl group and X is Cl. In another aspect of this embodiment, R is an ethyl group and X is Cl.

In another aspect, the diorganotin dihalide compounds of the formula R₂SnX₂ can also be converted to compounds of formula R₂SnL₂ via equation (II):

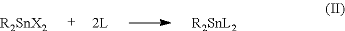

where L is a hydrolysable monoanionic ligand which can replace X via chemical exchange or other chemical reactions and L can be selected from the group of alkoxy (—OR¹), organoamino (—NR²R³), carboxylate (—OOCR⁴), amidinato (—R⁵N(CR⁶)NR⁷, imido (—N(COR⁸)(COR⁹), alkynido (—CCR¹⁰) where R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group with a proviso that R¹ cannot be hydrogen and R²⁻³ cannot both be hydrogen.

In another aspect, the disclosed and claimed subject matter includes using the above-described diorganotin dihalide compounds and/or the process for preparing the above-described diorganotin dihalide compounds as starting materials/steps to make other organotin compounds such as RSnX₃ or RSnL₃ which is suitable as starting material or precursor for further formation of EUV photoresist composition as spin coating material or precursor for vapor deposition. For example, compounds of formula RSnX₃ can be made from the precursors via equation (III):

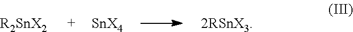

Compounds of formula RSnX₃ can in turn be converted to compounds of formula RSnL₃ via equation (IV):

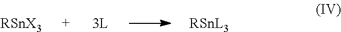

where L is a hydrolysable monoanionic ligand which can replace X via chemical exchange or other chemical reactions and L can be selected from the group of alkoxy (—OR¹), organoamino (—NR²R³), carbloxylate (—OOCR⁴), amidinato (—R⁵N(CR⁶)NR⁷, imido (—N(COR⁸)(COR⁹), alkynido (—CCR¹⁰) where R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group.

In another aspect, the disclosed and claimed subject matter includes using the above-described diorganotin dihalide compounds and/or the process for preparing the above-described diorganotin dihalide compounds in methods for synthesizing precursors of the formula RₙSnX₄₋ₙ where R is an organic ligand with 1-31 carbon atoms bound to Sn with a metal-carbon bond, n=1-3 and X is a ligand having a hydrolysable bond with Sn, such as described in U.S. Pat. No. 10,732,505 (which is herein incorporated by reference in its entirety).

In another aspect, the disclosed and claimed subject matter includes using the above-described diorganotin dihalide compounds and/or the process for preparing the above-described diorganotin dihalide compounds in a method for synthesizing monoalkyltin triamide compounds, the method including, reacting an alkylating agent selected from the group of RMgX, R₂Zn, RZnNR′₂, or a combination thereof, with Sn(NR′₂)₄ in a solution including an organic solvent, where R is a hydrocarbyl group with 1-31 carbon atoms, where X is a halogen, and where R′ is a hydrocarbyl group with 1-10 carbon atoms, such as described in U.S. Pat. No. 10,73287,466 (which is herein incorporated by reference in its entirety).

In another aspect, the disclosed and claimed subject matter includes using the above-described diorganotin dihalide compounds and/or the process for preparing the above-described diorganotin dihalide compounds in a process for synthesizing an adjusted precursor solution for a radiation patternable coating including a mixture of an organic solvent and a first monoalkyltin trialkoxide (RSn(OR′)₃) having a tin concentration that is from about 0.004 M to about 1.0 M, the method including: mixing the organic solvent and the first monoalkyltin trialkoxide to form the adjusted precursor solution, where the solvent has been adjusted to have a water content to within ±15 percent of a selected value and where the adjusted water content is no more than 10,000 ppm by weight (such as described in U.S. Patent Application Publication No. 2019/0391486 which is herein incorporated by reference in its entirety), where the first monoalkyltin trialkoxide is prepared from the above-described diorganotin dihalide compounds and/or the process for preparing the above-described diorganotin dihalide compounds.

In another aspect, the disclosed and claimed subject matter includes using the diorganotin dihalide compounds of the disclosed and claimed subject matter in or to prepare formulations that are useful in EUV processes. Such formulations are or can be used for patterning a radiation sensitive coating in a process that includes (i) forming a coating on a substrate surface with a precursor solution where the precursor solution (a) was prepared from the above-described diorganotin dihalide compounds and/or utilized the process for preparing the same, (b) has a uniform composition resulting from adjusting the water content of the solvent used to form the adjusted precursor solution within about ±15% of a target value and (c) has a selected water content is from about 300 ppm by weight to about 10,000 ppm by weight; (ii) drying the coating; and (iii) irradiating the dried coating to form a latent image.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

As used herein, “C_{x-y}” (where x and y are each integers) designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantyl and the like). Suitable acyclic groups can be methyl, ethyl, n-or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. As mentioned herein the cyclic alkyl groups may have any of the acyclic alkyl groups as substituent. These alkyl moieties may be substituted or unsubstituted.

“Halogenated alkyl” refers to a linear, cyclic or branched saturated alkyl group as defined above in which one or more of the hydrogens has been replaced by a halogen (e.g., F, Cl, Br and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

“Alkoxy” (a.k.a. “alkyloxy”) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

“Alkyl carbonyl” refers to an alkyl group as defined above which is attached through a carbonyl group (—C(═O—)) moiety (e.g., methylcarbonyl, ethylcarbonyl, propylcarbonyl, butylcarbonyl, cyclopentylcarbonyl and the like). These alkyl carbonyl moieties may be substituted or unsubstituted.

“Halo” or “halide” refers to a halogen (e.g., F, Cl, Br and I).

“Hydroxy” (a.k.a. “hydroxyl”) refers to an —OH group.

The term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, 1-phenylethyl (Ph(Me)CH—), 1-phenyl-1-methyl-ethyl (Ph(Me)₂C—), benzyl, chlorobenzyl, tolyl, o-xylyl, 1,2,3-triazolyl, pyrrrolyl, and furanyl.

Unless otherwise indicated, the term “substituted” when referring to an alkyl, alkoxy, fluorinated alkyl and the like refers to one of these moieties which also contains one or more substituents including, but not limited, to the following substituents: alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties where no substituents apart from hydrogen are present.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

### Diorganotin Dihalide Compounds

As set forth above, the disclosed subject matter relates to diorganotin dihalide compounds of the formula R₂SnX₂ (where (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group and (ii) X is Cl, Br, F or I) that as-synthesized (i.e., without further purification) are free of the corresponding tetraalkyltin (R₄Sn), trialkyltin halide (R₃SnX) and monoalkyltin trihalide (RSnX₃) species.

In one aspect of this embodiment, R is a methyl group in the diorganotin dihalide compounds of the formula R₂SnX₂. In another aspect of this embodiment, R is an ethyl group in the diorganotin dihalide compounds of the formula R₂SnX₂. In one aspect of this embodiment, X is Cl in the diorganotin dihalide compounds of the formula R₂SnX₂. In another aspect of this embodiment, R is a methyl group and X is Cl in the diorganotin dihalide compounds of the formula R₂SnX₂ (i.e., dimethyltin dichloride; Me₂SnCl₂). In another aspect of this embodiment, R is an ethyl group and X is Cl in the diorganotin dihalide compounds of the formula R₂SnX₂ (i.e., diethyltin dichloride; Et₂SnCl₂).

In one aspect of this embodiment, the compounds of the formula R₂SnX₂ have a purity of about 98 wt % or higher based on analytical methods such as NMR, GC or other standard analytical methods.

In one aspect of this embodiment, the compounds of the formula R₂SnX₂ have a purity of about 98.5 wt % or higher based on analytical methods such as NMR, GC or other standard analytical methods.

In one aspect of this embodiment, the compounds of the formula R₂SnX₂ have a purity of about 99 wt % or higher based on analytical methods such as NMR, GC or other standard analytical methods.

In one aspect of this embodiment, the compounds of the formula R₂SnX₂ have a purity of about 99.5 wt % or higher based on analytical methods such as NMR, GC or other standard analytical methods.

As discussed in more detail below, the diorganotin dihalide compounds of the disclosed and claimed subject matter, including in particular Me₂SnCl₂ and Et₂SnCl₂, are (i) as-synthesized (i.e., without further purification) free of the corresponding tetraalkyltin (R₄Sn; e.g., (Me)₄Sn), trialkyltin halide (R₃SnX; e.g., (Me)₃SnX) and monoalkyltin trihalide (RSnX₃; e.g., MeSnX₃) species and (ii) can be used to in or to prepare other precursors and/or formulations that are useful in deposition and EUV processes.

### Processes for Preparing Diorganotin Dihalide Compounds

As set forth above, the disclosed subject matter relates to the synthesis of diorganotin dihalide compounds of the formula R₂SnX₂ from a diorganotin oxide (R₂SnO) according to synthesis (I):

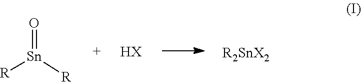

where (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group and (ii) X is Cl, Br, F or I. The resulting compound of formula R₂SnX₂ as-synthesized (i.e., without further purification) are free of the corresponding tetraalkyltin (R₄Sn), trialkyltin halide (R₃SnX) and monoalkyltin trihalide (RSnX₃) species.

In one aspect of this embodiment, R is a methyl group in the diorganotin oxide (R₂SnO) compound (i.e., dimethytin oxide; (Me)₂SnO). In another aspect of this embodiment, R is an ethyl group in the diorganotin oxide (R₂SnO) compound (i.e., diethytin oxide; (Et)₂SnO). Commercially available diorganotin oxide (R₂SnO) compounds include, but are not limited to, dibutyltin (IV) oxide, dioctyltin oxide and bis(3,3,4,4,5,5,6,6,7,7,8,8,8-tridecafluorooctyl)tin oxide; other desirable diorganotin oxide (R₂SnO) compounds can be synthesized.

Examples of diorganotin dihalide compounds of the formula R₂SnX₂ made according to the above-described synthesis and that as-synthesized are free of tetraalkyltin (R₄Sn), trialkyltin halide (R₃SnX) and monoalkyltin trihalide (RSnX₃) include, but are not limited to, those described in Table 1:

TABLE 1

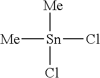

Dimethyltin dichlorides

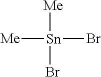

Dimethyltin dibromides

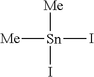

Dimethyltin diiodides

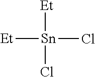

Diethyltin dichlorides

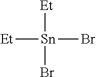

Diethyltin dibromides

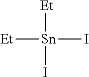

Diethyltin diiodides

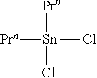

Di-n-propyltin dichlorides

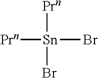

Di-n-propyltin dibromides

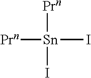

Di-n-propyltin diiodides

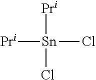

Di-iso-propyltin dichlorides

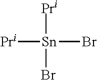

Di-iso-propyltin dibromides

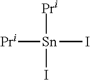

Di-iso-propyltin diiodides

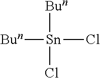

Di-n-butyltin dichlorides

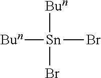

Di-n-butyltin dibromides

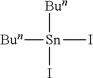

Di-n-butyltin diiodides

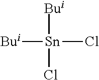

Di-iso-butyltin dichlorides

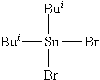

Di-iso-butyltin dibromides

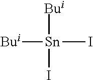

Di-iso-butyltin diiodides

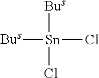

Di-sec-butyltin dichlorides

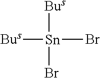

Di-sec-butyltin dibromides

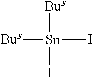

Di-sec-butyltin diiodides

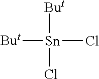

Di-tert-butyltin dichlorides

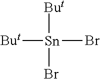

Di-tert-butyltin dibromides

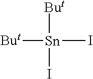

Di-tert-butyltin diiodides

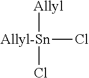

Di-allylltin dichlorides

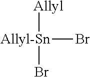

Di-allylltin dibromides

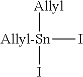

Di-allylltin diodidides

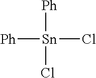 [SMILES: [Cl][Sn]([Cl])([c]1ccccc1)[c]1ccccc1]

Di-phenyltin dichlorides

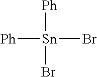 [SMILES: [Br][Sn]([Br])([c]1ccccc1)[c]1ccccc1]

Di-phenyltin dibromides

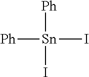 [SMILES: [I][Sn]([I])([c]1ccccc1)[c]1ccccc1]

Di-phenyltin diiodides

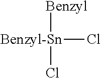

Di-benzyltin dichlorides

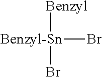

Di-benzyltin dibromides

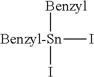

Di-benzyltin diiodides

In one aspect of this embodiment, it is preferred that R is a methyl group in the diorganotin dihalide compounds of the formula R₂SnX₂. In another aspect of this embodiment, it is preferred that R is an ethyl group in the diorganotin dihalide compounds of the formula R₂SnX₂. In one aspect of this embodiment, it is preferred that X is Cl in the diorganotin dihalide compounds of the formula R₂SnX₂. In another aspect of this embodiment, it is preferred that R is a methyl group and X is Cl in the diorganotin dihalide compounds of the formula R₂SnX₂ (i.e., dimethyltin dichloride; Me₂SnCl₂). In another aspect of this embodiment, it is preferred that R is an ethyl group and X is Cl in the diorganotin dihalide compounds of the formula R₂SnX₂ (i.e., diethyltin dichloride; Et₂SnCl₂).

The process for synthesizing the disclosed and claimed diorganotin dihalide compounds of the formula R₂SnX₂ includes the steps of:
(i) forming a mixture of diorganotin oxide (R₂SnO) where (i) R is an unsubstituted linear C₁-C₁₀ alkyl group, a linear C₁-C6 alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group with an appropriate organic solvent;
(ii) adding an aqueous solution of an acid of the formula HX (where X=one of Cl, Br, F or I) to the mixture of step (i) to form a biphasic mixture (i.e., an organic phase and an aqueous phase);
(iii) stirring the biphasic mixture of step (ii) for a period of time;
(iv) separating the organic phase and an aqueous phase of the biphasic mixture;
(v) optionally further extracting the aqueous phase;
(vi) isolating the compound of the formula R₂SnX₂; and
(vii) optionally purifying the compound of the formula R₂SnX₂.

In step (i), the diorganotin oxide (i.e., R₂SnO) is combined with an appropriate organic solvent to form a mixture. As noted, R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group. In one aspect of this embodiment, R is a methyl group (i.e., dimethytin oxide; (Me)₂SnO). In another aspect of this embodiment, R is an ethyl group (i.e., diethytin oxide; (Et)₂SnO).

In step (i), any appropriate solvent can be used. Examples of such solvents include, but are not limited to linear, branched, cyclic or poly-ethers (e.g., tetrahydrofuran (THF), diethyl ether, diglyme, and/or tetraglyme); linear, branched, or cyclic alkanes, alkenes, aromatics and halocarbons (e.g., pentane, hexanes, toluene and dichloromethane) and combinations thereof. Preferred solvents include toluene and dichloromethane (aka methylene chloride). A particularly preferred solvent is methylene chloride. When prepared, the mixture can be in slurry form.

In step (ii), an aqueous solution of an acid of formula HX (where X=one of Cl, Br, F or I) is added to the mixture of diorganotin oxide (e.g., dimethyl tin oxide and organic solvent) from step (i). In one aspect of this embodiment, the acid is HCl. In one aspect of this embodiment, the acid is HBr. In one aspect of this embodiment, the acid is HF. In one aspect of this embodiment, the acid is HI. The addition of the aqueous solution of the acid creates a biphasic mixture (that includes an organic phase and an aqueous phase) due to the presence of water in the acid solution. It should be noted that the amount of water in the acid solution can vary and/or be adjusted as desired or needed. In one embodiment, the diorganotin oxide is dimethytin oxide ((Me)₂SnO), the solvent comprises methylene chloride and the aqueous acid comprises HCl. In another embodiment, the diorganotin oxide is diethytin oxide ((Et)₂SnO), the solvent comprises methylene chloride and the aqueous acid comprises HCl.

In step (iii), the biphasic mixture from step (ii) is stirred for a period of time. The length of time can be relatively short (e.g., 10-60 minutes) but can be longer as desired. In one aspect, the process reaction time is from about 10 minutes to about 12 hours. In another aspect, the reaction time is from about 10 minutes to about 10 hours. In another aspect, the reaction time is from about 10 minutes to about 6 hours. In another aspect, the reaction time is from about 10 minutes to about 3 hours. In another aspect, the reaction time is from about 10 minutes to about 1 hour. In another aspect, the reaction time is from about 10 minutes to about 30 minutes.

In step (iv), and following the stirring, the aqueous and organic phases of the biphasic mixture are separated. The separation can be accomplished by any acceptable process.

In step (v), the aqueous phase optionally can be further extracted to recover more of the diorganotin dihalide compounds of the formula R₂SnX₂. This extraction can be conducted using any suitable solvent (e.g., those solvents listed above). In one embodiment, it is performed using the same solvent employed in step (i). For example, in one aspect of this embodiment, the aqueous layer is extracted with additional methylene chloride.

In step (vi), the compound of the formula R₂SnX₂ are isolated. In this step, the organic solvent used are removed. The removal of the solvents can be conducted using any suitable procedure(s). Thereafter, the isolated materials can be reconstituted in any suitable solvent. In one aspect of this embodiment, the isolated materials can be reconstituted in any toluene.

As noted above, the as-synthesized compounds of formula R₂SnX₂ (e.g., Me₂SnCl₂) are inherently free of the corresponding tetraalkyltin (R₄Sn), trialkyltin halide (R₃SnX) and monoalkyltin trihalide (RSnX₃) species. However, in step (vii), the compound of the formula R₂SnX₂ are optionally further purified to remove other impurities. The purification can be conducted using any suitable procedure(s). In one aspect, the compound of the formula R₂SnX₂ can be purified via distillation. In another aspect, the compound of the formula R₂SnX₂ can be purified via crystallization. In one aspect, the compound of the formula R₂SnX₂ is purified to provide a purity of about 98 wt % or higher based on analytical methods such as NMR, GC or other standard analytical methods. In another aspect, the compound of the formula R₂SnX₂ is purified to provide a purity of about 99 wt % or higher based on analytical methods such as NMR, GC or other standard analytical methods. In another aspect, the compound of the formula R₂SnX₂ is purified to provide a purity of about 99.5 wt % or higher based on analytical methods such as ¹H NMR, GC or other standard analytical methods.

In one aspect, some or all of the steps of the process are conducted at a temperature of between about −40° C. to a temperature which is at or below the boiling point of the solvent(s) employed. In another aspect, some or all of the steps of the process are conducted at a temperature of between about −40° C. to about 100° C. In another aspect, some or all of the steps of the process are conducted at a temperature of between about −40° C. to about 30° C. In another aspect, some or all of the steps of the process are conducted at a temperature of between about −40° C. to about room temperature. In another aspect, all of the steps are performed at a temperature of between about −40° C. to a temperature which is at or below the boiling point of the solvent(s) employed. In another aspect, all of the steps of the process are performed at room temperature.

In one aspect, the yield of compound of the formula R₂SnX₂ from the process is about or above 80%. In another aspect, the yield of compound of the formula R₂SnX₂ from the process is about or above 85%. In another aspect, the yield of compound of the formula R₂SnX₂ from the process is about or above 90%. In another aspect, the yield of compound of the formula R₂SnX₂ from the process is about or above 95%.

### Uses of Diorganotin Dihalide Compounds and the Processes for Preparing the Same

As noted above, in another aspect, the diorganotin dihalide compounds of the formula R₂SnX₂ can also be converted to compounds of formula R₂SnL₂ via equation (II):

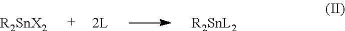

where L is a hydrolysable monoanionic ligand which can replace X via chemical exchange or other chemical reactions and L can be selected from the group of alkoxy (—OR¹), organoamino (—NR²R³), carboxylate (—OOCR⁴), amidinato (—R⁵N(CR⁶)NR⁷, imido (—N(COR⁸)(COR⁹), alkynido (—CCR¹⁰) where R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group with the proviso that R¹ cannot be hydrogen and R²⁻³ cannot both be hydrogen.

In another aspect, the disclosed and claimed subject matter includes using the above-described diorganotin dihalide compounds and/or the process for preparing the above-described diorganotin dihalide compounds as starting materials/steps to make other organotin compounds such as RSnX₃ or RSnL₃ which is suitable as starting material or precursor for further formation of EUV photoresist composition as spin coating material or precursor for vapor deposition. For example, compounds of formula RSnX₃ can be made from the precursors via equation (III):

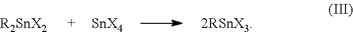

Compounds of formula RSnX₃ can in turn be converted to compounds of formula RSnL₃ via equation (IV):

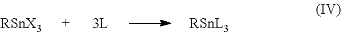

where L is a hydrolysable monoanionic ligand which can replace X via chemical exchange or other chemical reactions and L can be selected from the group of alkoxy (—OR¹), organoamino (—NR²R³), carboxylate (—OOCR⁴), amidinato (—R⁵N(CR⁶)NR⁷, imido (—N(COR⁸)(COR⁹), alkynido (—CCR¹⁰) where R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C3 to C₁₀ alkenyl group, a C₃ to C₁₀ alkynyl group, and a C₄ to C₁₀ aryl group with the proviso that R¹ cannot be hydrogen and R²⁻³ cannot both be hydrogen.

For example, the above-described diorganotin dihalide compounds of the formula R₂SnX₂ and/or the process for preparing the above-described diorganotin dihalide compounds can be used as starting materials/steps in chemical exchange reactions to make compounds of formula or R₂SnL₂ or RSnL₃ such as those exemplified in equations (V) and (VI):

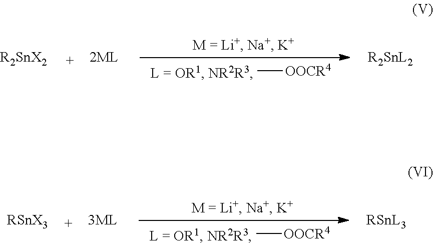

as described in, for example, Kennedy, J. D., “Auto-association in organometallic compounds: a nuclear magnetic double resonance study of methyl- and n-butyl-tin alkoxides.” J. Chem. Soc., Perkin Trans., 2(2): 242-248 (1977); Reuter, H. and D. Schroeder, “Preparation, crystal structure and reactions of isopropyltin triisopropoxide” J. Organomet. Chem., 455(1-2): 83-87 (1993); and Jones, K. and M. F. Lappert “Aminostannanes, stannylamines, and stannazanes.” Proc. Chem. Soc., London, 358-359, (1962), each of which is incorporated herein in its entirety.

Similarly, R₂SnL₂ or RSnL₃, where L=alkoxy or carboxylate, can also be made via reacting R₂SnX₂ or RSnX₃ with the corresponding alcohol or carboxylic acid in presence of organic amines as shown, for example, in equation (VII) (see, e.g. U.S. Patent Application Publication No. US2020/117085 A which is incorporated here in its entirety):

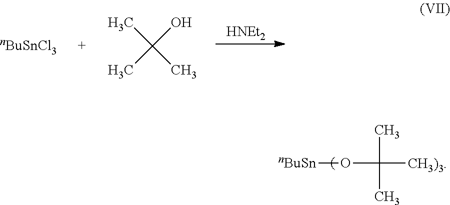

In another aspect, the disclosed and claimed subject matter includes using the above-described diorganotin dihalide compounds and/or the process for preparing the above-described diorganotin dihalide compounds in methods for synthesizing precursors of the formula RₙSnX₄₋ₙ where R is an organic ligand with 1-31 carbon atoms bound to Sn with a metal-carbon bond, n=1-3 and X is a ligand having a hydrolysable bond with Sn, such as described in U.S. Pat. No. 10,732,505 (which is herein incorporated by reference in its entirety). Such a process includes converting a compound of the formula R₂SnX₂ into the compound of the formula RₙSnX₄₋ₙ where n=1-3 and X is a ligand having a hydrolysable bond with Sn.

Other compounds of the formulae R₂SnL2 or RSnL₃ that can be prepared using the above-described diorganotin dihalide compounds and/or the process for preparing the above-described diorganotin dihalide compounds include: ^{t}Bu₂Sn(NEt₂)₂, ^{t}Bu₂Sn(NMe₂)₂, ⁿBu₂Sn(NMe₂)₂, ⁱPr₂Sn(NMe₂)₂, ^{t}Am₂Sn(NMe₂)₂, (cyclopentyl)₂Sn(NMe₂)₂, Me₂Sn(NMe₂)₂, (cyclobutyl)₂Sn(NMe₂)₂, (cyclopentyl)₂Sn(NMe₂)₂, (cyclohexyl)₂Sn(NMe₂)₂, ((C₆H₅)CH₂)₂Sn(NMe₂)₂, ((C₆H₅)(CH₃)CH)₂Sn(NMe₂)₂, ((C₆H₅)(CH₃)₂C)₂Sn(NMe₂)₂, ((CH₃)₂(CN)C)₂Sn(NMe₂)₂, ((CH₃)(CN)CH)₂Sn(NMe₂)₂, ^{t}Bu₂Sn(O^{t}Bu)₂, Me₂Sn(O^{t}Bu)₂, ⁿBu₂Sn(O^{t}Bu)₂, ⁱPr₂Sn(O^{t}Bu)₂, ^{t}Am₂Sn(O^{t}Bu)₂, (cyclobutyl)₂Sn(O^{t}Bu)₂, (cyclopentyl)₂Sn(O^{t}Bu)₂, (cyclohexyl)₂Sn(O^{t}Bu)₂, ((C₆H₅)CH₂)₂Sn(O^{t}Bu)₂, ((C₆H₅)(CH₃)CH)₂Sn(O^{t}Bu)₂, ((C₆H₅)(CH₃)₂C)₂Sn(O^{t}Bu)₂, ((CH₃)₂(CN)C)₂Sn(O^{t}Bu)₂, ((CH₃)(CN)CH)₂Sn(O^{t}Bu)₂, ^{t}Bu₂Sn(O^{t}Am)₂, Me₂Sn(O^{t}Am)₂, ⁿBu₂Sn(O^{t}Am)₂, ⁱPr₂Sn(O^{t}Am)₂, ^{t}Am₂Sn(O^{t}Am)₂ (cyclobutyl)₂Sn(O^{t}Am)₂, (cyclopentyl)₂Sn(O^{t}Am)₂, (cyclohexyl)₂Sn(O^{t}Am)₂, ((C₆H₅)CH₂)₂Sn(O^{t}Am)₂, ((C₆H₅)(CH₃)CH)₂Sn(O^{t}Am)₂, ((C₆H₅)(CH₃)₂C)₂Sn(O^{t}Am)₂, ((CH₃)₂(CN)C)₂Sn(O^{t}Am)₂, ((CH₃)(CN)CH)₂Sn(O^{t}Am)₂, ^{t}BuSn(NEt₂)₃, ^{t}BuSn(NMe₂)₃, ^{t}BuSn(O^{t}Bu)3, ⁱPrSn(NMe₂)₃, MeSn(O^{t}Bu)₃, ⁿBuSn(O^{t}Bu)₃, ⁿBuSn(NMe₂)₃, (CH₃)₃CSn(NMe₂)₃, (CH₃)₂CHSn(NMe₂)₃, (CH₃)₂(CH₃CH₂)CSn(NMe₂)₃, cyclopentylSn(NMe₂)₃, CH₃Sn(NMe₂)₃, cyclobutylSn(NMe₂)₃, cyclopentylSn(NMe₂)₃, cyclohexylSn(NMe₂)₃ (C₆H₅)CH₂Sn(NMe₂)₃, (C₆H₅)(CH₃)CHSn(NMe₂)₃, (C₆H₅)(CH₃)₂CSn(NMe₂)₃, (CH₃)₂(CN)CSn(NMe₂)₃, (CH₃)(CN)CHSn(NMe₂)₃, (CH₃)₃CSn(O^{t}Bu)₃, (CH₃)₂CHSn(O^{t}Bu)₃, (CH₃)₂(CH₃CH₂)CSn(O^{t}Bu)₃, (CH₂)₂CHSn(O^{t}Bu)₃, CH₃Sn(O^{t}Bu)₃, (CH₂)₃CHSn(O^{t}Bu)₃, (CH₂)₄CHSn(O^{t}Bu)₃, (C₆H₅)CH₂Sn(O^{t}Bu)₃, (C₆H₅)(CH₃)CHSn(O^{t}Bu)₃, (C₆H₅)(CH₃)₂CSn(O^{t}Bu)₃, (CH₃)₂(CN)CSn(O^{t}Bu)₃, (CH₃)(CN)CHSn(O^{t}Bu)₃, (CH₃)₃CSn(O^{t}Am)₃, (CH₃)₂CHSn(O^{t}Am)₃, (CH₃)₂(CH₃CH₂)CSn(O^{t}Am)₃, cyclopropylSn(O^{t}Am)₃, CH₃Sn(O^{t}Am)₃, cyclobutylSn(O^{t}Am)₃, cyclopentylSn(O^{t}Am)₃, cyclohexylSn(O^{t}Am)₃, (C₆H₅)CH₂Sn(O^{t}Am)₃, (C₆H₅)(CH₃)CHSn(O^{t}Am)₃, (C₆H₅)(CH₃)₂CSn(O^{t}Am)₃, (CH₃)₂(CN)CSn(O^{t}Am)₃, (CH₃)(CN)CHSn(O^{t}Am).

In another aspect, the disclosed and claimed subject matter includes using the above-described diorganotin dihalide compounds and/or the process for preparing the above-described diorganotin dihalide compounds in a process for synthesizing an adjusted precursor solution for a radiation patternable coating including a mixture of an organic solvent and a first monoalkyl tin trialkoxide (RSn(OR′)₃) having a tin concentration that is from about 0.004 M to about 1.0 M, the method including: mixing the organic solvent and the first monoalkyl tin trialkoxide to form the adjusted precursor solution, where the solvent has been adjusted to have a water content to within ±15 percent of a selected value and where the adjusted water content is no more than 10,000 ppm by weight (such as described in U.S. Patent Application Publication No. 2019/0391486 which is herein incorporated by reference in its entirety), where the first monoalkyl tin trialkoxide is prepared from the above-described diorganotin dihalide compounds and/or the process for preparing the above-described diorganotin dihalide compounds. In some embodiment, in the alkyl tin trialkoxide compositions of formula RSn(OR′)₃, R and R′ are independently hydrocarbyl groups, such as an alkyl or a cycloalkyl with 1-31 carbon atoms with one or more carbon atoms optionally substituted with one of more heteroatom functional groups containing O, N, Si, Ge, Sn, Te, and/or halogen atoms or an alkyl or a cycloalkyl further functionalized with a phenyl or cyano group. In some embodiments, R′ includes ≤10 carbon atoms and can be, for example, methyl, ethyl, propyl, isopropyl, butyl, t-butyl, isobutyl, or t-amyl. Such a process includes, for example, (i) converting a compound of the formula R₂SnX₂ into the first monoalkyl tin trialkoxide of formula RSn(OR′)₃ and (ii) mixing the organic solvent and the first monoalkyl tin trialkoxide to form the adjusted precursor solution, where (a) the solvent has been adjusted to have a water content to within ±15 percent of a selected value, (b) the adjusted water content is no more than 10,000 ppm by weight, and (c) R′is one or more of methyl, ethyl, propyl, isopropyl, butyl, t-butyl, isobutyl, or t-amyl. In one aspect of the this embodiment, the selected value is from about 250 ppm to about 10,000 ppm by weight. In another aspect of the this embodiment, the selected value is from about 300 ppm to about 5,000 ppm by weight.

In another aspect, the disclosed and claimed subject matter includes using the diorganotin dihalide compounds of the disclosed and claimed subject matter in or to prepare formulations that are useful in EUV processes. Such formulations are or can be used for patterning a radiation sensitive coating in a process that includes (i) forming a coating on a substrate surface with a precursor solution where the precursor solution (a) was prepared from the above-described diorganotin dihalide compounds and/or utilized the process for preparing the same, (b) has a uniform composition resulting from adjusting the water content of the solvent used to form the adjusted precursor solution within about ±15% of a target value and (c) has a selected water content from about 300 ppm by weight to about 10,000 ppm by weight; (ii) drying the coating; and (iii) irradiating the dried coating to form a latent image.

Another aspect of the disclosed and claimed subject matter is a composition comprising: 98 wt % or more of a diorganotin dihalide compound of the formula R₂SnX₂, as described above; 0 wt % of R₄Sn, R₃SnX and RSnX₃; and up to 2 wt % of other impurities.

Another aspect of the disclosed and claimed subject matter is the use of a diorganotin oxide (R₂SnO) as described above for preparing a diorganotin dihalide compound of the formula R₂SnX₂ as described above, which is as-synthesized free of R₄Sn, R₃SnX and RSnX₃.

It will also be apparent to those skilled in the art that various modifications may be made in how the disclosed subject matter is practiced based on described aspects in the specification without departing from the spirit and scope of the disclosed subject matter disclosed herein.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

The disclosed and claimed processes utilizes commercially available materials (e.g., dimethyl tin oxide, methylene chloride, etc.).

### Example 1: Synthesis of Dimethyltin Dichloride

A 22 L flask is fitted with a glass stir shaft and Teflon stir paddle, an industrial condenser, a 2.5 L addition funnel, a glass thermowell and a side arm adapter and flushed with nitrogen gas. dimethyl tin oxide, 1983 g, was charged to the flask. To this was charged 10 L of dichloromethane (CH₂Cl₂) and the slurry was set to stir. To the addition funnel was added 5.0 L of 12.2 M HCl in water (in two portions). This solution was added to the stirring slurry over a period of one hour, during which the temperature rose from about 24° C. to about 35° C. The slurry eventually became a clear yellow solution. The reaction was stirred for several hours and when it stopped stirring, layers quickly formed. The organic layer was separated from the aqueous layer and the aqueous layer was extracted three times with CH₂Cl₂ and the organic layers were combined, and the solvent was removed under vacuum. The solids were taken up in 2 L of toluene, heated to 70° C. and the flask was put into the cooler to crystallize material. Toluene filtered off material and the colorless solids were washed with cold pentane and put under vacuum to dry. Dimethyltin dichloride (2385 g; 90% yield) was isolated as a free-flowing powder. No corresponding tetraalkyltin, trialkyltin halide or monoalkyltin trihalide species were detected by ¹H NMR/¹¹⁹Sn NMR.

### Comparative Example

Me₂SnCl₂ was prepared from tetramethyltin and tin tetrachloride in a neat (no solvent) reaction with stirring for 15-16 hours at 90-135° C. Solvent was then added to the mixture and cooled to induce crystallization. The crystals were then isolated and washed to remove any residual toxic impurities. The supernatant liquid containing up to 4% of the methyltin chloride was bottled and moved to hazardous waste for appropriate disposal. No tetraalkyltin was detected. The final material was tested as >99% purity of Me₂SnC₁₂.

Although the Me₂SnCl₂ of the comparative method could be purified after considerable workup of the reaction, it could not be synthesized directly (i.e., in situ) in that manner without detectable impurities. In contrast, the current method directly yields diorganotin dihalide compounds that as-synthesized are entirely free of tetra or trialkyltin species because the “raw” R₂SnO starting material contains no tri or tetraalkyltin impurities. Addition of the HX to the R₂SnO species creates only the corresponding R₂SnX₂ species which is isolated in greater than 99.5% purity and in some cases 99.9% purity by GC and ¹H NMR/¹¹⁹Sn NMR.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1-11. (canceled)

11. A process for preparing a diorganotin dihalide compound of the formula R₂SnX₂
wherein: (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, a substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group, and
(ii) X is Cl, Br, F or I; and
wherein the diorganotin dihalide compound as-synthesized is free of R₄Sn, R₃SnX and RSnX₃,
comprising the steps of
(i) forming a mixture of diorganotin oxide (R₂SnO) where (i) R is an unsubstituted linear C₁-C₁₀ alkyl group, a linear C₁-C₆ alkyl group substituted with a halogen, a linear C₁-C₆ alkyl group substituted with an amino group, an unsubstituted branched C₃-C₁₀ alkyl group, a branched C₃-C₁₀ alkyl group substituted with a halogen, a branched C₃-C₁₀ alkyl group substituted with an amino group, an unsubstituted amine, an substituted amine, —Si(CH₃)₃, a C₃-C₈ unsubstituted cyclic alkyl group, a C₃-C₈ cyclic alkyl group substituted with a halogen, a C₃-C₈ cyclic alkyl group substituted with an amino group, a C₃-C₈ unsubstituted aromatic group, a C₃-C₈ aromatic group substituted with a halogen, a C₃-C₈ aromatic group substituted with an amino group, a C₃ to C₁₀ heterocyclic group, a C₃ to C₁₀ alkenyl group and a C₃ to C₁₀ alkynyl group with an organic solvent;
(ii) adding an aqueous solution of an acid of the formula HX wherein X is one of Cl, Br, F or I to the mixture of step (i) to form a biphasic mixture comprising an organic phase and an aqueous phase;
(iii) stirring the biphasic mixture of step (ii) for a period of time;
(iv) separating the organic phase and an aqueous phase of the biphasic mixture;
(v) optionally further extracting the aqueous phase;
(vi) isolating the compound of the formula R₂SnX₂; and
(vii) optionally purifying the compound of the formula R₂SnX₂.

12. The process of claim 11, wherein R is a methyl group.

13. The process of claim 11, wherein R is an ethyl group.

14. The process of claim 11, wherein X is Cl.

15. The process of claim 11, wherein R is a methyl group and X is Cl.

16. The process of claim 11, wherein R is an ethyl group and X is Cl.

17. The process of claim 11, wherein the diorganotin oxide is dimethytin oxide ((Me)₂SnO).

18. The process of claim 11, wherein the diorganotin oxide is diethytin oxide ((Et)₂SnO).

19. The process of claim 11, wherein the solvent comprises one or more of a linear, branched, cyclic or poly-ether, linear, branched, or cyclic alkanes, alkenes, aromatics and halocarbons and combinations thereof.

20. The process of claim 11, wherein the solvent comprises methylene chloride.

21. The process of claim 11, wherein the aqueous acid comprises HCl.

22. The process of claim 11, wherein the aqueous acid comprises one or more of HBr, HF and HI.

23. (canceled)

24. (canceled)

25. The process of claim 11, wherein the diorganotin oxide is dimethyltin oxide ((Me)₂SnO), the solvent comprises methylene chloride and the aqueous acid comprises HCl.

26. The process of claim 11, wherein the diorganotin oxide is diethyltin oxide ((Et)₂SnO), the solvent comprises methylene chloride and the aqueous acid comprises HCl.

27. The process of claim 11, wherein the step (iii) period of time is from about 10 minutes to about 12 hours.

28-33. (canceled)

34. The process of claim 11, wherein the compound of the formula R₂SnX₂ is isolated using a solvent comprising toluene.

35. The process of claim 11, wherein the compound of the formula R₂SnX₂ is purified via one or more of distillation and crystallization.

36. (canceled)

37. The process of claim 11, wherein some or all of the steps of the process are conducted at a temperature of between about −40° C. to a temperature which is at or below the boiling point of the solvent(s) employed.

38. The process of claim 11, wherein some or all of the steps of the process are conducted at a temperature of between about −40° C. to about 100° C.

39-42. (canceled)

43. The process of claim 11, wherein yield of compound of the formula R₂SnX₂ is about or above 80%.

44-46. (canceled)

47. The process of claim 11 further comprising converting the compound of the formula R₂SnX₂ to a compound of formula R₂SnL₂, wherein L is one or more of an alkoxy (—OR¹), an organoamino (—NR²R³), a carboxylate (—OOCR⁴), an amidinato (—R⁵N(CR⁶)NR⁷, an imido (—N(COR⁸)(COR⁹), an alkynido (—CCR¹⁰), wherein R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group with the proviso that R¹ cannot be hydrogen and R₂₋₃ cannot both be hydrogen.

48. The process of claim 11 further comprising converting the compound of the formula R₂SnX₂ to a compound of formula RSnL₃, wherein L is one or more of an alkoxy (—OR¹), an organoamino (—NR²R³), a carboxylate (—OOCR⁴), an amidinato (—R⁵N(CR⁶)NR⁷, an imido (—N(COR⁸)(COR⁹), an alkynido (—CCR¹⁰), wherein R¹⁻¹⁰ are each independently selected from hydrogen, a linear C₁ to C₁₀ alkyl group, a branched C₃ to C₁₀ alkyl group, a C₃ to C₁₀ cyclic alkyl group, a C₃ to C₁₀ heterocyclic group, a C₃ to C₁₀ alkenyl group, a C₃ to C₁₀ alkynyl group, and a C₄ to C₁₀ aryl group with the proviso that R¹ cannot be hydrogen and R²⁻³ cannot both be hydrogen.

49. The process of claim 11 further comprising converting the compound of the formula R₂SnX₂ to a compound of the formula RₙSnX₄₋ₙ wherein n=1-3 and X is a ligand having a hydrolysable bond with Sn.

50. The process of claim 11 further comprising converting the compound of the formula R₂SnX₂ to one or more of ^{t}Bu₂Sn(NEt₂)₂, ^{t}Bu₂Sn(NMe₂)₂, ⁿBu₂Sn(NMe₂)₂, ⁱPr₂Sn(NMe₂)₂, ^{t}Am₂Sn(NMe₂)₂, (cyclopentyl)₂Sn(NMe₂)₂, Me₂Sn(NMe₂)₂, (cyclobutyl)₂Sn(NMe₂)₂, (cyclopentyl)₂Sn(NMe₂)₂, (cyclohexyl)₂Sn(NMe₂)₂, ((C₆H₅)CH₂)₂Sn(NMe₂)₂, ((C₆H₅)(CH₃)CH)₂Sn(NMe₂)₂, ((C₆H₅)(CH₃)₂C)₂Sn(NMe₂)₂, ((CH₃)₂(CN)C)₂Sn(NMe₂)₂, ((CH₃)(CN)CH)₂Sn(NMe₂)₂, ^{t}Bu₂Sn(O^{t}Bu)₂, Me₂Sn(O^{t}Bu)₂, ⁿBu₂Sn(O^{t}Bu)₂, ⁱPr₂Sn(O^{t}Bu)₂,^{t}Am₂Sn(O^{t}Bu)₂, (cyclobutyl)₂Sn(O^{t}Bu)₂, (cyclopentyl)₂Sn(O^{t}Bu)₂, (cyclohexyl)₂Sn(O^{t}Bu)₂, ((C₆H⁵)CH₂)₂Sn(O^{t}Bu)₂, ((C₆H₅)(CH₃)CH)₂Sn(O^{t}Bu)₂, ((C₆H₅)(CH₃)₂C)₂Sn(O^{t}Bu)₂, ((CH₃)₂(CN)C)₂Sn(O^{t}Bu)₂, ((CH₃)(CN)CH)₂Sn(O^{t}Bu)₂, ^{t}Bu₂Sn(O^{t}Am)₂, Me₂Sn(O^{t}Am)₂, ⁿBu₂Sn(O^{t}Am)₂, ⁱPr₂Sn(O^{t}Am)₂, ^{t}Am₂Sn(O^{t}Am)₂ (cyclobutyl)₂Sn(O^{t}Am)₂, (cyclopentyl)₂Sn(O^{t}Am)₂, (cyclohexyl)₂Sn(O^{t}Am)₂, ((C₆H₅)CH₂)₂Sn(O^{t}Am)₂, ((C₆H₅)(CH₃)CH)₂Sn(O^{t}Am)₂, ((C₆H₅)(CH₃)₂C)₂Sn(O^{t}Am)₂, ((CH₃)₂(CN)C)₂Sn(O^{t}Am)₂, ((CH₃)(CN)CH)₂Sn(OₜAm)₂, ^{t}BuSn(NEt₂)₃, ^{t}BuSn(NMe₂)₃, ^{t}BuSn(O^{t}Bu)3, ⁱPrSn(NMe₂)₃, MeSn(O^{t}Bu)₃, ⁿBuSn(O^{t}Bu)₃, ⁿBuSn(NMe₂)₃, (CH₃)₃CSn(NMe₂)₃, (CH₃)₂CHSn(NMe₂)₃, (CH₃)₂(CH₃CH₂)CSn(NMe₂)₃, cyclopentylSn(NMe₂)₃, CH₃Sn(NMe₂)₃, cyclobutylSn(NMe₂)₃, cyclopentylSn(NMe₂)₃, cyclohexylSn(NMe₂)₃ (C₆H₅)CH₂Sn(NMe₂)₃, (C₆H₅)(CH₃)CHSn(NMe₂)₃, (C₆H₅)(CH₃)₂CSn(NMe₂)₃, (CH₃)₂(CN)CSn(NMe₂)₃, (CH₃)(CN)CHSn(NMe₂)₃, (CH₃)₃CSn(O^{t}Bu)₃, (CH₃)₂CHSn(O^{t}Bu)₃, (CH₃)₂(CH₃CH₂)CSn(O^{t}Bu)₃, (CH₂)₂CHSn(O^{t}Bu)₃, CH₃Sn(O^{t}Bu)₃, (CH₂)₃CHSn(O^{t}Bu)₃, (CH₂)₄CHSn(O^{t}Bu)₃, (C₆H₅)CH₂Sn(O^{t}Bu)₃, (C₆H₅)(CH₃)CHSn(O^{t}Bu)₃, (C₆H₅)(CH₃)₂CSn(O^{t}Bu)₃, (CH₃)₂(CN)CSn(O^{t}Bu)₃, (CH₃)(CN)CHSn(O^{t}Bu)₃, (CH₃)₃CSn(O^{t}Am)₃, (CH₃)₂CHSn(O^{t}Am)₃, (CH₅)₂(CH₃CH₂)CSn(O^{t}Am)₃, cyclopropylSn(O^{t}Am)₃, CH₃Sn(O^{t}Am)₃, cyclobutylSn(O^{t}Am)₃, cyclopentylSn(O^{t}Am)₃, cyclohexylSn(O^{t}Am)₃, (C₆H₅)CH₂Sn(O^{t}Am)₃, (C₆H₅)(CH₃)CHSn(O^{t}Am)₃, (C₆H₅)(CH₃)₂CSn(O^{t}Am)₃, (CH₃)₂(CN)CSn(O^{t}Am)₃, (CH₃)(CN)CHSn(O^{t}Am).

51-57. (canceled)
